(19) United States
(12) Patent Application Publication
(10) Pub. No.: US 2010/0109651 A1
(43) Pub. Date: May 6, 2010

(54) DEVICE FOR CONDUCTIVITY MEASUREMENT IN A CONTROLLED ENVIRONMENT AND METHOD THEREOF

(76) Inventors: Yuriy V. Tolmachev, Kent, OH (US); Evgeny M. Garanin, Kent, OH (US)

Correspondence Address: FAY SHARPE LLP, 1228 Euclid Avenue, 5th Floor, The Halle Building, Cleveland, OH, 44115, US

(21) Appl. No.: 12/500,726

(22) Filed: Jul. 10, 2009

Related U.S. Application Data
(60) Provisional application No. 61/080,018, filed on Jul. 11, 2008.

(51) Int. Cl. G01R 1/06

(52) U.S. Cl. 324/149

(57) ABSTRACT

The invention provides a device for measuring the conductivity in a controlled environment and method thereof. The device comprises (i) a sample comprising a first material such as protonic conductor, (ii) an environmental medium comprising a controlled level of a second material such as water vapor, and (iii) a separator such as a sample holder. The separator isolates the sample from the environmental medium; the separator substantially prevents the first material from migrating into the environmental medium; and the separator allows the second material to migrate between the environmental medium and the sample. The invention resolves the problems of e.g. interfacial impedance, humidity equilibration and the loss of contact between the sample and the electrode upon sample shrinking.

This application claims priority based on the U.S. Provisional Application Ser. No. 61/080,018 filed on Jul. 11, 2008, which is incorporated herein by reference in its entirety.

### BACKGROUND OF THE INVENTION

The present invention is related to a device for measuring the conductivity of materials in a controlled environment and a method thereof. It finds particular application in conjunction with the measurement of a sample such as powder in an environmental medium such as an air/water vapor mixture, and will be described with particular reference thereto. However, it is to be appreciated that the present invention is also amenable to other like applications.

In response to requirements of the fuel cell industry, numerous materials have been studied in recent years as low-humidity proton conductors in different temperature regions. These include acid surface functionalized nanostructures, heteropolyacids, phosphate and/or silicate glasses, hydrogen sulfates and phosphates, and ceramic doped double oxides. In order to make fuel cell membranes, these materials are often converted into composites with better mechanical properties.

Nevertheless, the conductivity of single phase non-castable ionic materials often needs to be measured in the powder form before the best candidates for the composite development can be selected. Therefore, the intrinsic conductivity of pure powdered materials is of a significant interest.

The conductivity of powders is usually measured using ac impedance after compressing the powder into a pellet and depositing electrodes on or pressing electrodes against the two flat sides of the pellet. This design does not allow for a quick equilibration between the water/oxygen content in the sample and that in the surrounding, and complicates the analysis of the sample's impedance spectra due to the presence of two interfacial capacitances. The latter problem is exacerbated by the small thickness of a typical pellet, and, thus, smaller resistance and higher ac frequencies needed for accurate resistance measurements. Also, this approach is applicable only to materials that form free-standing pellets which do not disintegrate due to the Rehbinder effect in the studied range of humidity. Reported in Holmberg, B. A.; Yan, Y. S. Journal of the Electrochemical Society 2006, 153, A146-A149 (hereinafter “Holmberg and Van”) was a new cell design that allows for conductivity measurements on a loose powder placed into a cylindrical hole and squeezed between two fixed rod electrodes. This design, however, does not resolve three problems including the interfacial impedance, the humidity equilibration and the loss of contact between the sample and the electrode upon sample shrinking.

Advantageously, the present invention provides an improvement over Holmberg and Yan's design by using, for example, four electrodes, a porous cell material and spring-loads on the current collector electrodes to overcome the three aforementioned problems. The invention may be used in for example measuring conductivity of powders under variable humidity and temperature.

### BRIEF DESCRIPTION OF THE INVENTION

One aspect of the invention is to provide a device for measuring the conductivity of a sample, which comprises:
(i) a sample comprising a first material,
(ii) an environmental medium comprising a controlled level of a second material, and
(iii) a separator;
wherein the separator isolates the sample from the environmental medium;
the separator substantially prevents the first material from migrating into the environmental medium; and
the separator allows the second material to migrate between the environmental medium and the sample.

Another aspect of the invention provides a method of measuring the conductivity of a sample, for example, the conductivity of a deformable sample as a function of humidity and/or temperature, which comprises a step of using the device comprising:
(i) a sample comprising a first material,
(ii) an environmental medium comprising a controlled level of a second material, and
(iii) a separator;
wherein the separator isolates the sample from the environmental medium;
the separator substantially prevents the first material from migrating into the environmental medium; and
the separator allows the second material to migrate between the environmental medium and the sample.

### BRIEF DESCRIPTION OF THE DRAWINGS

FIG. 1 shows the “4-point probe circuit” as embodied in a device according to an embodiment of the invention;

FIGS. 2 and 3 show a device comprising a sample holder made from porous zirconium phosphate according to an embodiment of the invention;

FIG. 4 shows the dependence of the conductivity of a powder sample on pressure between two outer electrodes;

FIG. 5 shows the conductivity of a powder sample measured with two and four electrodes at different ac frequencies;

FIG. 6 shows the dependence of the phase shift between current and voltage on ac frequency in impedance measurements with two and four electrodes; and

FIG. 7 shows conductivities of a film sample and a powder sample both of which were prepared from the same material as functions of relative humidity.

### DETAILED DESCRIPTION OF THE INVENTION

As the separator allows the second material to migrate between the environmental medium and the sample, there is an equilibrium between the second material in the environmental medium and that in the sample, such as water equilibrium. In exemplary embodiments, the environmental medium is in a phase selected from gas phase, liquid phase, solid phase, a phase there-in-between, and any combination thereof. When the environmental medium is a liquid phase, it can be selected from aqueous phase, non-aqueous phase, and any combination thereof.

In exemplary embodiments, the second material is selected from ions such as H⁺ and OH⁻; neutral molecules such as water, acids, bases, and solvents; complexing agents; and any combination thereof.

In exemplary embodiments, the environmental medium is a gas phase and the second material is selected from inert or reactive gases and vapors such as water vapor, hydrogen, oxygen, and any combination thereof.

In exemplary embodiments, the environmental medium is in gas phase; the second material is water vapor; and the level of the water vapor in the gas phase is controlled by a humidity controller, with which the invention provides a method of measuring the conductivity of a sample as a function of humidity. A suitable humidity controller may be selected from a saturated salt solution, a bubble humidifier, a membrane humidifier, and any combination thereof.

In exemplary embodiments, the environmental medium is in gas phase; and the separator is a sample holder made of a material permeable to the second material such as water vapor.

Examples of material permeable to the second material include, but are not limited to, ceramic materials, plastic materials, metallic materials, porous materials such as zirconium phosphate and borosilicate glass, and any combination thereof. For example, the utilization of a porous sample holder allows for easy control of the water activity in the sample.

In exemplary embodiments, the invention provides a device for measuring the conductivity of a sample, which comprises:
(i) a sample comprising a first material,
(ii) an environmental medium comprising a controlled level of a second material,
(iii) a separator, and
(iv) at least two electrodes;
wherein the separator isolates the sample from the environmental medium;
the separator substantially prevents the first material from migrating into the environmental medium;
the separator allows the second material to migrate between the environmental medium and the sample; and
the pressure controller controls the contact pressure at the interface between the sample and the at least two electrodes.

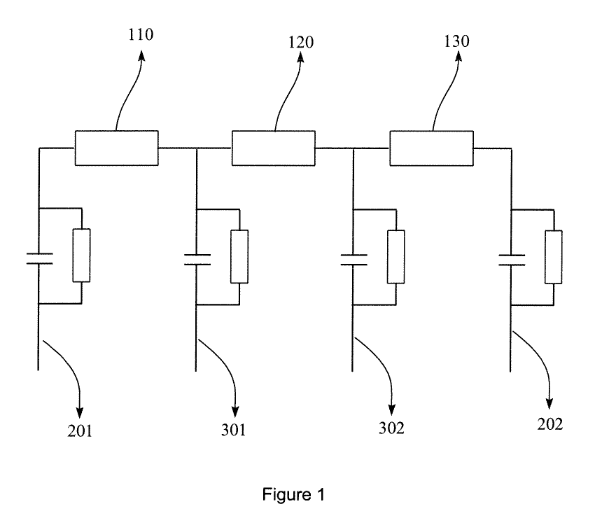

In exemplary embodiments, the device of the invention comprises at least four electrodes, wherein at least two of the at least four electrodes are inner electrodes located within the sample, and at least two of the at least four electrodes are outer electrodes located on the sides of the sample. In a specific embodiment, the device of the invention embodies a circuit, a “4-point probe circuit” as shown in FIG. 1.

With reference to FIG. 1, two inner electrodes 301 and 302 and two outer electrodes 201 and 202 can be viewed to separate the sample into three segments 110, 120, and 130. As a part of the measurement of the sample segment 120, resistance R₁₂₀ of the sample segment 120 can be calculated by measuring the voltage V between the two inner electrodes 301 and 302, and the current I between the two outer electrodes 201 and 202, according to the equation R₁₂₀=V/I.

In the “4-point probe circuit” as shown in FIG. 1, every electrode/sample such as electrolyte interface can be approximated for the purposes of its electric properties as a parallel combination of a double layer capacitance, Cd, and a faradaic resistance, Rf. The Cd is due to the fact that neither electrons nor ions can cross the interface and they accumulate on the surface of the respective materials. Rf is due to electrochemical reaction, which allows for the flow of electrons across the interface. Rf is large for small voltages (no electrode reactions) and Rf is small for high voltages (electrolysis). By measuring the current between 201 and 202 and the voltage between 301 and 302, the impedance of 120 can be obtained. For all practical purposes, the current flowing between two inner electrodes 301 and 302 is zero. The currents through 110, 120, and 130 are the same.

The invention thus can provide a simple method to measure, for example, the conductivity of powders using four-electrode ac impedance spectroscopy, which is not affected by the dimensional changes of the sample. The problems of interfacial impedance and of maintaining constant inter-electrode distance are resolved by the 4 point nature of the cell. One reason for using AC is to reduce the “battery” effect, i.e. the voltage difference between the two inner electrodes which is due to different chemical environment, temperature and pressure differences.

In exemplary embodiments, the pressure controller controls both the contact pressure at the interface between the sample and the outer electrodes; and the stress of the sample applied on the inner electrodes. For example, the pressure controller may be selected from spring, elastomeric member, hydraulic pump, pneumatic pump, and any combination thereof.

In an example, the invention takes advantage of a spring-loaded contact electrode, which prevents the loss of contact upon sample shrinking. The implementation of four-electrode AC impedance measurements effectively reduces the inaccuracy due to interfacial capacitance of the probes.

In exemplary embodiments, the device of the invention comprises a distance detector that measures the distance between the two inner electrodes for the final acquisition of conductivity value. Suitable distance detectors may be selected from X-ray Computed Axial Tomography (CAT), X-ray Projection Photography, Magnetic Resonance Imaging, and any combination thereof.

In exemplary embodiments, the invention provides a device for measuring the conductivity of a sample, which comprises:
(i) a sample comprising a first material,
(ii) an environmental medium comprising a controlled level of a second material,
(iii) a separator, and
(iv) a temperature controller;
wherein the separator isolates the sample from the environmental medium;
the separator substantially prevents the first material from migrating into the environmental medium;
the separator allows the second material to migrate between the environmental medium and the sample; and
the temperature controller controls the temperature of the sample and of the environmental medium.

In exemplary embodiments, the invention provides a method of measuring the conductivity of a sample as a function of temperature, which comprises a step of using such a device. As such, the invention is particularly useful for low-humidity proton conductors for different temperature regions.

Examples of suitable temperature controllers include, but are not limited to, electrical heating tape, sand bath, oil bath, oven, and any combination thereof.

The conductivity to be measured may be selected from electronic conductivity and ionic conductivity such as cationic conductivity, anionic conductivity, and any combination thereof. In exemplary embodiments, the cationic conductivity is selected from conductivities of H⁺, Ag⁺, Li⁺, Cd²⁺, Hg²⁺, and any combination thereof; and the anionic conductivity is selected from conductivities of O²⁻, F⁻, S²⁻, and any combination thereof. In preferred embodiments, the conductivity is protonic (H⁺) conductivity.

In exemplary embodiments, the conductivity is AC conductivity or DC conductivity.

The present invention may be used on various samples such as powder, monolith, ceramic, metal, elastomeric material, gel, plastic, liquid, and any combination thereof. In preferred embodiments, the sample comprises a proton conductor. Examples of proton conductors include, but are not limited to, ionic polymers, sulfonated polymers, acid surface functionalized nanostructures, ionic liquids, acid-doped polymers, heteropolyacids, phosphate and/or silicate glasses, hydrogen sulfates and phosphates, ceramic doped double oxides, and any combination thereof. In preferred embodiments, these proton conductors can be in powder form.

The invention can be used to measure the conductivities of powdered samples. Because the powder is exposed to the environment, the invention can be used to measure the conductivity as a function of temperature and relative humidity of the environment.

With the present invention, protonic conductivity of powders can be measured under variable and controlled humidity conditions using a porous holder for the sample.

### EXAMPLE 1

### A Test Device

This example comprises a rectangular box with cylindrical holes drilled in porous zirconium phosphate. One large hole is drilled lengthwise through the box. A sample such as a powder sample was put into this cylindrical channel. Two outer electrodes with a pressure controller such as two spring loaded metal electrodes are inserted into the openings at the ends and pushed against the powder with constant pressure. Two smaller holes are drilled perpendicular in the middle of the box, intersecting the large channel. Inner electrodes such as Pt wires are inserted into these smaller channels and penetrate through the entire width.

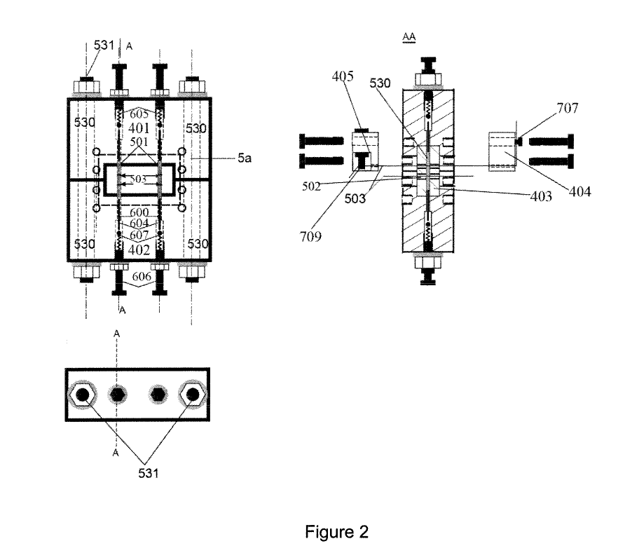

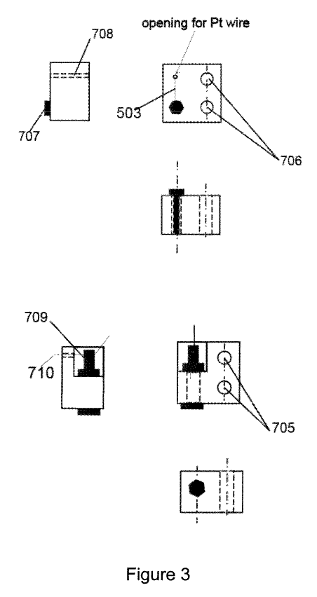

The device consists of three pieces as shown in FIGS. 2 and 3. The top 401 and bottom 402 pieces are identical in shape and made of e.g. polyetherimide (PEI, ULTEM 1000, McMaster #7612K15). A separator such as a sample holder e.g. center piece 403 is made from porous zirconium phosphate (Aremco #502-1550, with μm range pore size and 30% porosity). Porous borosilicate glass (Ace Glass #D129888, porosity E: 4-8 μm) as the material for the central piece can also be used and test proved it was successful. Reference electrode wire holders 404 and 405 are shown disassembled for side view only.

The powder sample was loaded into one of the two vertical straight-through holes 501 in the central piece. The central piece is placed between the cavities made in the plastic pieces, and the whole assembly is held together by two threaded stainless steel rods 531 that go through the outer holes 530 in the plastic pieces.

The powder in the hole 501 in the central piece 403 is compressed between two Pt-rods 600 (for example, 1.50 mm diameter, 15.0 mm long, Tanaka Kikinzoku Kogyo) that enter each hole 501 through inner holes 604 in the plastic pieces. The pressure on each rod is produced by a compression stainless steel spring 605 (McMaster #9662K14, 0.125″ OD, 8.0 mm free length), one of each which is placed into the inner holes 604 of the plastic pieces as shown in FIGS. 2 and 3. The pressure was applied to the spring 605 using a screw 606 (e.g. UTS 8-32, 1″ long) threaded into hole 604. To assure a better mechanical and electrical contact between the spring 605 and the rod 531, a stainless steel ball bearing 607 (e.g. ⅛″ inch diameter, McMaster #9291K14) is placed in between. Since for the torques used in this work the spring is under full compression, a spring with a larger Hooke's coefficient may be used. This however will require larger diameter inner holes in the plastic pieces.

The two Pt rods 600 inserted in holes 501 through holes 604 are used as the outer electrodes in the four-electrode impedance cell. The inner electrodes are two Pt wires 503 (e.g. 0.15 mm thick) that go through horizontal holes 502 in the center piece for example 5.0 mm apart. Each wire 503 is held in place by two polyetherimide holders (404 and 405) attached with screws (e.g. UTS 6-32 0.7″ long) through holes (705 and 706) to the two opposite sides on the corresponding plastic piece (401 for the upper wire and 402 for the lower wire). Each back holder 404 has a fixed screw 707 to which a Pt wire 503 is attached. From the point of attachment the wire 503 goes vertically into a wire hole 708 where it bends horizontally and directed through a centerpiece hole 502. On the other side of the center piece the wire 503 is attached through hole 710 to a machine head 709 on the front holder 405. Two enantiomorphs of both the front and back holders are used at the opposite corners of the center piece 403.

There are no specific limitations on the dimensions of the device. For example, vertical straight-through holes 501 in the central piece can have a diameter of from about 0.1 mm to about 10 mm such as 1.50 mm diameter. The threaded stainless steel rods 531 can have a length of from about 1 cm to about 100 cm, such as 10.0 cm. The distance from an edge of pieces 401 and 402 to the center of the outer holes 530 can be from 0.1 mm to 1000 mm, such as 7.8 mm. Pt-rods 600 can have a diameter of from about 0.1 mm to about 10 mm, such as 1.50 mm diameter and a length of from about 1 mm to about 100 mm, such as 15.0 mm. Similarly, top and bottom pieces 401 and 402 can have a length of from about 5 mm to about 1000 mm, such as 40 mm, a thickness of from about 1 mm to 1000 mm, such as 25 mm and a width of from about 1 mm to 1000 mm, such as 70 mm. The distance from the edge of pieces 401 and 402 to the center of inner holes 604 can be from about 1 mm to about 1000 mm, such as 25 mm. The hole 604 is composed of two openings, on a top of each other, and can be from 1 mm to 1000 mm, such as 27.5 mm. The larger opening accommodates a screw, a spring and a stainless steel ball. This larger opening can have a length of from 1 to 1000 mm, such as 20 mm, and can have a diameter of from 0.1 mm to 1000 mm, such as 3.5 mm. The length of the threaded part of the larger opening can be from 1 mm to 1000 mm such as 10 mm. The smaller opening of 604 can have a length of from 1 to 1000 mm such as 7.5 mm and a diameter from 0.1 mm to 1000 mm, such as 1.5 mm. Similarly, central piece 403 can have a length from 1 mm to 1000 mm, such as 40 mm, a thickness of from 0.1 mm to 1000 mm, such as 10 mm and a height of from 1 mm to 1000 mm, such as 25 mm. The vertical straight-through holes 501 can have a diameter of from 0.01 mm to 1000 mm, such as 1.5 mm. Reference electrodes or Pt-wires can be 0.1 to 1000 mm apart, such as 5 mm, and can have a diameter of from 0.01 mm to 100 mm, such as 0.25 mm. Polyetherimide holders 404 and 405 can have dimensions of from 0.1×0.1×0.1 mm to 1000×1000×1000 mm, such as 19×19×12.7. Similarly, holes 706 and 705 can have diameters of from 0.1 mm to 1000 mm, such as 4 mm. The distance between the edges of 404 and 405 holders to the centers of the 706 and 705 holes can be from 0.1 mm to 1000 mm, such as 4 mm. The diameter of the 708 hole can be from 0.01 mm to 100 mm, such as 1 mm. Likewise, the hole which accommodates a screw 707 can have a diameter from 0.1 mm to 1000 mm, such as 3 mm. The distance between the centers of 706 and 705 holes can be from 0.1 mm to 1000 mm, such as 9 mm.

### EXAMPLE 2

### Conductivity Measurement

Using the device of Example 1, a comparison between the conductivities of an extruded Nafion film and a Nafion powder at different humidities has been made. The data shows that the conductivity of a powder is several times lower than the conductivity of a film, which is likely due to the porous nature and intergrain resistances in the powder.

The conductivity of the Nafion film was measured using a four-electrode conductivity clamp (BekkTech BT-110). Both the powder cell and the film clamp were placed into a 1 L custom-made high-pressure environmental chamber (Parr, Moline, Ill.) equipped with a humidity-temperature sensor (Vaisala HMT330), electrical feedthroughs and gas inlet/outlet valves. The chamber temperature can be maintained using a temperature controller (Omega CN 8200) connected to an electrical heating tape (Barnstead international #BIH101-060) and several thermistors positioned inside the chamber. All data reported was obtained at room temperature (23±0.5° C.). The relative humidity in the chamber was controlled using saturated salt solutions placed in a glass beaker on the bottom of the chamber and it was stable within 0.2%. Impedance data was acquired using a Solartron 1287 Electrochemical Interface and 1255B Frequency Response Analyzer under ZPlot software (Scribner Associates, Inc.). The frequency of the ac perturbation was step-scanned in the region from 1 MHz to 1 Hz with the amplitude of 100 mV.

The powder Nafion was obtained by grinding a wet film of Nafion 950 (equivalent weight EW=950 g/mol H⁺) (IonPower Inc.) in liquid nitrogen using a stainless steel mortar and a glass pestle. Both powder and film Nafion samples were boiled in 3% H₂O₂ for 4 hours, in deionized water (18.2 MΩ·cm conductivity) for 2 hours, in 1.0 M HClO₄ for 2 hours and then again in deionized water 3 times.

Prior to a powder sample loading, the two Pt wires 503 and the first Pt rod 600 were inserted into one of the center piece holes 501 with the rod touching the lower wire from below. The powder was poured into the vertically held hole via the upper opening until it covered the upper wire (5-10 mg). The second rod 600 was inserted into the upper opening and the central piece was turned upside down and the first rod 600 as taken out. Another portion of the powder (2-5 mg) was poured in and the powder in the hole was finger-pressed between the rods. The process of pouring and compressing was repeated until the distance between the two Pt rods reached 10-15 mm (4-8 times). If needed, the second hole 501 in the center piece was filled in the same way.

After the filling process, the center piece 403 was sandwiched between the top 401 and bottom 402 fixture pieces. The two treated stainless steel rods 531 were inserted into side opening 530 and tightened with two nuts to hold the three fixture pieces together. A ball bearing 607, a spring 605, a nut, a washer and a screw 606 were inserted in the hole 604 in the top piece and finger-tightened; then the procedure was repeated for the bottom part. After this, the screws 606 were tightened to the desired torque using a torque screwdriver.

After assembly, the two Pt wires 503 were extended through holes 708 and 710 of the back 404 and front 405 holders, respectively. The holders were screwed though smooth holes 706 to threaded holes 705 of the top 401 and bottom 402 pieces. The two Pt wires 503 were wrapped around screws 707 of the back holders 404. Then, the other end of each wire 503 was wrapped around screw 709 of the front holder 405. The distance between Pt rods in the assembled cell was measured, if needed, using X-ray Computed Axial Tomography (CAT).

The cell with powder Nafion and BekkTech Conductivity Clamp with film Nafion and saturated salt solution was loaded into the pressure vessel. The vessel was sealed and vacuum was applied to speed up the diffusion of water vapor from the salt solution to the samples. The humidity sensor typically showed stable relative humidity values within 5 hours after the vacuum valve was closed. In some experiments a non-flammable mixture of 4% v/v H₂ in He was used inside the chamber. The H₂ stabilized the dc potential on the reference Pt electrodes 503 and the He increased the heat conductivity inside the chamber, thus, yielding more uniform temperature distribution.

### EXAMPLE 3

### Effect of the Applied Stress

Holmberg and Yan reported a strong effect of the torque applied to rods on the conductivity of their ceramic powder squeezed between the rods. This may be understood as the resulting pressure increasing the contact area and decreasing the spacing between the powder particles. Using the device of Example 1, this effect was investigated for Nafion powder.

The sample was loaded into a test fixture hole 501, the screws 606 were tightened to the lowest desired torque using a torque screwdriver, and a full impedance spectrum was acquired. After this, the torque was increased and a new impedance spectrum was recorded. The cycle was repeated until conductivity became independent of torque. In order to determine the compressive stress on the sample, P, the minimal torque required to loosen the screw, T_{backward}, was measured in separate experiments with the washer of screw 606 removed.

The stress of the sample powder was estimated using the following relationships between T_{forward} , T_{backward}, and the torques due to static (i=s) or dynamic (i=d) friction of the screw, Tⁱ_{friction}, and due to compressive stress of the sample, T_{compr}:

T_{forward}=T^{d}_{friction}T_{compr} (1)

T_{backward}=T^{s}_{friction}−T_{compr} (2)

Since it was observed that the value of T_{forward} is much higher than the value of T_{backward} in all cases, the following equation applies:

T_{compr}≈T^{s}_{friction} (3)

Assuming T^{s}_{friction}≈T^{d}_{friction}, one obtains:

T_{compr}≈T_{forward}/2 (4)

For an infinitely small increment of the rotation angle eq. (1) yields:

T_{forward}dφ=T^{d}_{friction}dφ+T_{compr}dφ (5)

which based on the definition of stress, P, and eq. (4) reduces to

T_{forward}dφ≈2 PAδ(dφ/2π) (6)

where δ is the screw thread pitch ( 1/32″) and A is the cross-sectional area of the powder column with radius r. Therefore,

P≈T_{forward}/(δ*r²) (7)

Then, using the relationship [N·m]=141.6 [inch·oz·force], it can be concluded that

P [MPa]≈15.8 T_{forward} [inch·oz·force] (8)

Holmberg and Yan used a different approach to calculating the stress from the torque, based on the estimation of the friction force via a tabulated friction coefficient and making no distinction between dynamic and static friction. They obtained values of stress of about half of the values calculated based on eq. (8).

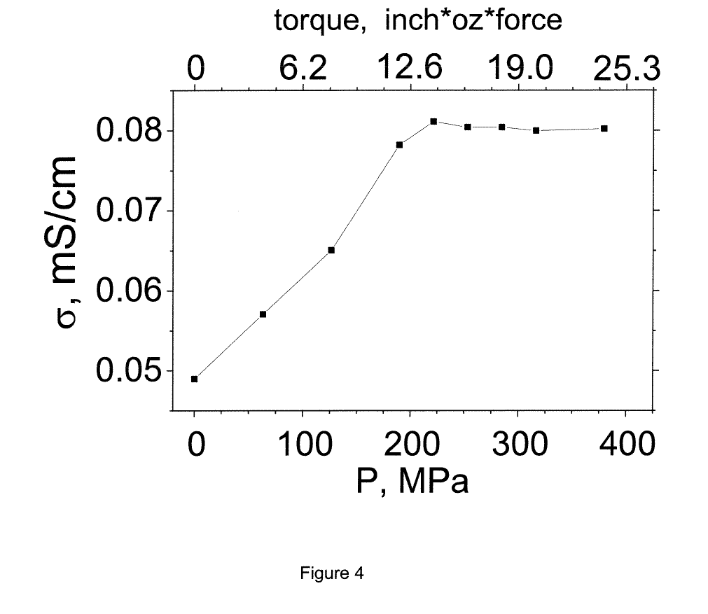

A typical dependence of powder conductivity on applied stress is shown in FIG. 4. Specifically, FIG. 4 shows the dependence of the conductivity of Nafion 950 powder on pressure between Pt rod electrodes. Experimental conditions were 23° C., 17.3% RH, and four-electrode measurements. As expected, the conductivity of the Nafion powder increased with applied pressure until or up to about ca. 200 MPa and remains constant at higher pressures up to at least 350 MPa. This behavior was reproducible with fresh powder samples at all humidities studied. All subsequent data was acquired in the plateau region, i.e. at 300 MPa.

### EXAMPLE 3

### Comparison Between Two- and Four-Electrode Conductivity Measurements

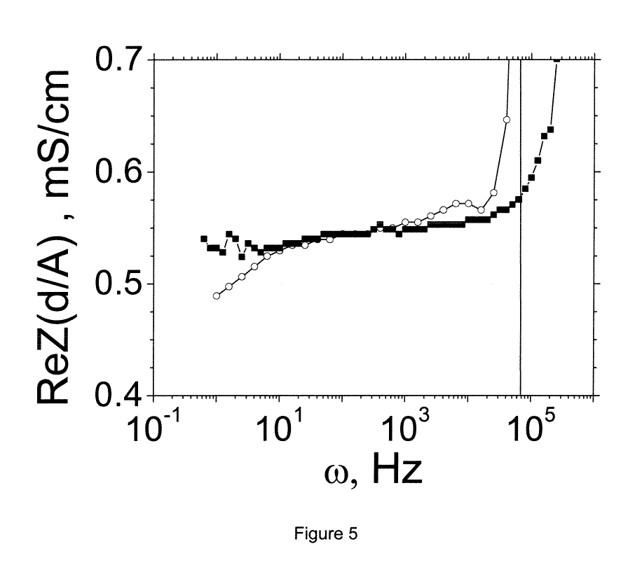

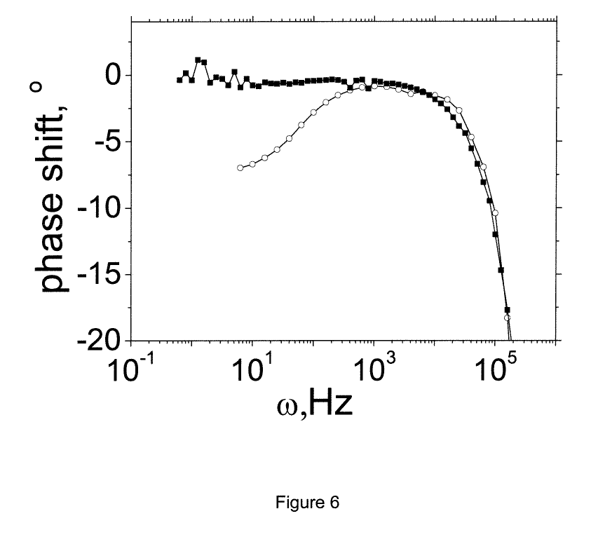

The double-layer capacitance at the interface between an electron conductor and an ion conductor imposes restrictions on the ranges of conductivities and frequencies that can be accurately measured using ac impedance spectroscopy. Increasing the ac frequency reduces the effect of the capacitance on the impedance, but in practice the effect of parasitic impedances and of the finite rise time of operational amplifiers makes such measurements inaccurate as can be seen from FIGS. 5 and 6. FIG. 5 shows the conductivity of Nafion 950 powder measured with two (d=20. mm thickness, open circles) and four (d=5.0 mm thickness, solid squares) electrodes at different ac frequencies under experimental conditions of 23° C., 32.1% RH, 300 MPa. and A=7.065 mm². FIG. 6 shows the dependence of the phase shift between current and voltage on ac frequency in impedance measurements with two (open circles) and four (solid squares) electrodes under experimental conditions of 23° C., 32.1% RH, and 300 MPa.

The resistance of the sample can be increased (thus shifting the RC transition frequency to lower values) by using thicker samples. This approach works reasonably well for Nafion sample also as can be seen in FIGS. 5 and 6 for the two-electrode data, but it may be of little use for samples with higher conductivity. i.e. 0.1 S/cm such as for Nafion under full hydration.

Even at 32.1% RH for Nafion, the phase shift and the modulus of the two-electrode impedance deviate from a pure resistive behavior below 300 Hz as shown in FIGS. 5 and 6 (open circles), apparently due to the presence of a serial double-layer capacitance combined with the phase-error of the lock-in amplifier (the latter is noticeable below 10 Hz in FIG. 5). The use of a four-electrode arrangement allows for extension of distortion-free measurements to lower frequencies (FIGS. 3 and 4, solid squares). All conductivity, σ, data were calculated from the real part of the measured four-electrode impedance at a frequency that shows the smallest modulus of the phase shift (typically in the 80-2000 Hz range).

### EXAMPLE 4

### Comparison Between Powder and Film Conductivities at Different Humidities

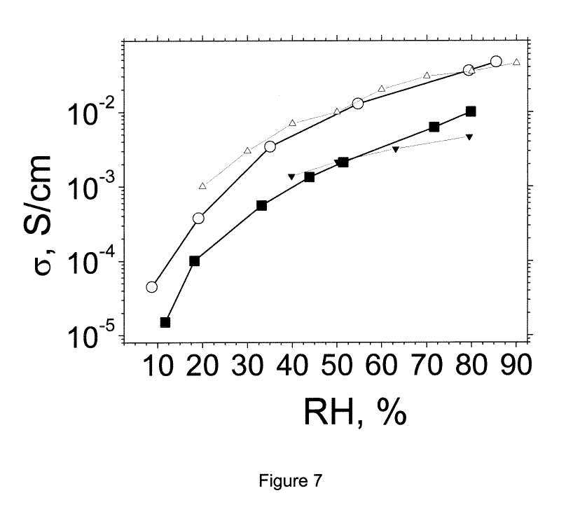

FIG. 7 shows conductivities of film and powder samples prepared from the same piece of a commercial Nafion 950 membrane as a function of relative humidity. More specifically, FIG. 7 shows the dependence of the conductivity of Nafion with EW=950 powder (solid squares) and film (open circles) on relative humidity. Experimental conditions: 23° C., 300 MPa, four-electrode measurement. Also shown are literature data for films of Nafion with EW=1100: in-plane at 20-80° C. (open up triangles), through-plane at 20° C. (filled down triangles), and through-plane at 80° C. (filled up triangles) (see Kreuer, K. D.; Schuster, M.; Obliers, B.; Diat, O.; Traub, U.; Fuchs, A.; Klock, U.; Paddison, S. J.; Maier, J. Journal of Power Sources 2008, 178, 499-509).

The values for the film are close to the previously reported values for through-plane conductivity of Nafion with EW of 1100 in the range 20-80° C. (See Lin, J.-C.; Kunz, H. R.; Fenton, J. A. In Handbook of Fuel Cells: Fundamentals, Technology and Applications; Vielstich, W., Lamm, A., Gasteiger, H., Eds.; Wiley, 2003; Vol. 3. Ch. 36; pp 456-463; and Lepiller, C.; Gauthier, V.; Gaudet, J.; Pereira, A.; Lefevre, M.; Guay, D.; Hitchcock, A. Journal of the Electrochemical Society 2008, 155, B70-B78). On the other hand, the conductivity of the powder is 3.5-5.5 times lower than the conductivity of the film under the same conditions and closer to the values reported recently for through-plane conductivity of Nafion 1100 at 20° C., as reported in Marechal, M.; Souquet, J. L.; Guindet, J.; Sanchez, J. Y. Electrochemistry Communications 2007, 9, 1023-1028. Three effects can contribute to the lower conductivity of the powder: anisotropy of Nafion conductivity, intergrain resistance, and voids/tortuosity in the powder structure. The latter two are also responsible for the pressure dependence of the powder conductivity.

The exemplary embodiments have been described with reference to the preferred embodiments. Obviously, modifications and alterations will occur to others upon reading and understanding the preceding detailed description. It is intended that the exemplary embodiment be construed as including all such modifications and alterations insofar as they come within the scope of the appended claims or the equivalents thereof.

1. A device for measuring the conductivity of a sample, which comprises:
(i) a sample comprising a first material,
(ii) an environmental medium comprising a controlled level of a second material, and
(iii) a separator;
wherein the separator isolates the sample from the environmental medium;
the separator substantially prevents the first material from migrating into the environmental medium; and
the separator allows the second material to migrate between the environmental medium and the sample.

2. The device according to claim 1, in which the environmental medium is in a phase selected from gas phase, liquid phase, solid phase, a phase there-in-between, and any combination thereof.

3. The device according to claim 1, in which the environmental medium is a liquid phase selected from aqueous phase, non-aqueous phase, and any combination thereof.

4. The device according to claim 3, in which the second material is selected from ions such as H⁺ and OH⁻; neutral molecules such as water, acids, bases, and solvents; complexing agents; and any combination thereof.

5. The device according to claim 1, in which the environmental medium is a gas phase.

6. The device according to claim 5, in which the second material is selected from inert or reactive gases and vapors such as water vapor, hydrogen, oxygen, and any combination thereof.

7. The device according to claim 1, in which the environmental medium is in gas phase; the second material is water vapor; and the level of the water vapor in the gas phase is controlled by a humidity controller.

8. The device according to claim 7, in which the humidity controller is selected from a saturated salt solution, a bubble humidifier, a membrane humidifier, and any combination thereof.

9. The device according to claim 1, in which the environmental medium is in gas phase; and the separator is a sample holder made of a material permeable to the second material such as water vapor.

10. The device according to claim 9, in which the material permeable to the second material is selected from ceramic materials, plastic materials, metallic materials, porous materials such as zirconium phosphate and borosilicate glass, and any combination thereof.

11. The device according to claim 1, which further comprises at least two electrodes and a pressure controller that controls the contact pressure at the interface between the sample and the at least two electrodes.

12. The device according to claim 11, which comprises at least four electrodes, wherein at least two of the at least four electrodes are inner electrodes located within the sample, and at least two of the at least four electrodes are outer electrodes located on the sides of the sample.

13. The device according to claim 12, wherein the pressure controller controls both the contact pressure at the interface between the sample and the outer electrodes; and the stress of the sample applied on the inner electrodes.

14. The device according to claim 11, in which the pressure controller is selected from spring, elastomeric member, hydraulic pump, pneumatic pump, and any combination thereof.

15. The device according to claim 11, which further comprises a distance detector that measures the distance between the two inner electrodes.

16. The device according to claim 15, in which the distance detector is selected from X-ray Computed Axial Tomography (CAT), X-ray Projection Photography, Magnetic Resonance Imaging, and any combination thereof.

17. The device according to claim 1, which further comprises a temperature controller that controls the temperature of the sample and of the environmental medium.

18. The device according to claim 17, in which the temperature controller is selected from electrical heating tape, sand bath, oil bath, oven, and any combination thereof.

19. The device according to claim 1, in which the conductivity is selected from electronic conductivity and ionic conductivity.

20. The device according to claim 19, in which the ionic conductivity is selected from cationic conductivity, anionic conductivity, and any combination thereof.

21. The device according to claim 20, in which the cationic conductivity is selected from conductivities of H⁺, Ag⁺, Li⁺, Cd²⁺, Hg²⁺, and any combination thereof; and the anionic conductivity is selected from conductivities of O²⁻, F⁻, S²⁻, and any combination thereof.

22. The device according to claim 1, in which the conductivity is protonic (H⁺) conductivity.

23. The device according to claim 1, in which the conductivity is AC conductivity or DC conductivity.

24. The device according to claim 1, in which the sample is selected from powder, monolith, ceramic, metal, elastomeric material, gel, plastic, liquid, and any combination thereof.

25. The device according to claim 1, in which the sample comprises a proton conductor.

26. The device according to claim 25, in which the proton conductor is selected from ionic polymers, sulfonated polymer, acid surface functionalized nanostructures, Ionic liquids, acid-doped polymers, heteropolyacids, phosphate and/or silicate glasses, hydrogen sulfates and phosphates, ceramic doped double oxides, and any combination thereof.

27. A method of measuring the conductivity of a sample, which comprises a step of using the device of claim 1.
